(19) United States
(12) Patent Application Publication
(10) Pub. No.: US 2007/0066060 A1
(43) Pub. Date: Mar. 22, 2007

(54) Semiconductor devices and fabrication methods thereof

(75) Inventor: Gin-Jei Wang, Taipei City 108 (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/230,125

(22) Filed: Sep. 19, 2005

(51) Int. Cl. H01L 21/4763

(52) U.S. Cl. 438/685; 438/637; 438/643; 438/648; 257/774; 257/763; 257/751

(57) ABSTRACT

Semiconductor devices and fabrication methods thereof. An opening is formed in a first dielectric layer, exposing an active region of the transistor, and an tungsten-containing barrier is conformably formed in the opening, with a thickness less than 50 Å. A tungsten layer is formed over the atomic layer deposited (ALD) tungsten-containing barrier to fill the opening.

### BACKGROUND

The present invention relates to semiconductors, and in particular to a semiconductor devices with contacts or interconnects having tungsten-containing barriers at minimal thickness and fabrications thereof.

In the manufacture of integrated circuits, a titanium nitride film is often used as a material barrier layer to inhibit the diffusion of metals into an underlying region beneath the barrier layer. These underlying regions include transistor gates, capacitor dielectrics, semiconductor substrates, metal lines, and many other integrated circuit structures.

A combination of titanium/titanium nitride (Ti/TiN) is often used as a diffusion barrier and provides contacts to the source and drain of a transistor. In the formation of a contact plug using a tungsten (W) plug process, for example, a Ti layer is deposited on a silicon substrate, followed by conversion of the Ti layer into titanium silicide (TiSiₓ), which provides a lower resistance contact with Si. A TiN layer is then formed upon the TiSix layer, prior to formation of the tungsten plug. Then tungsten (W) is deposited by chemical vapor deposition (CVD) from tungsten hexafluroride (WF₆).

The titanium/titanium nitride (Ti/TiN) combination layer formed by physical vapor deposition (PVD) such as sputtering, however, is problematic. The WF₆ molecules can diffuse between the TiN and react with titanium during the tungsten deposition, thus causing failure such as peeling of the TiN layer. Moreover, the formed titanium/titanium nitride combination layer has a certain thickness, thereby the contact resistance of the tungsten contact plug is increased. In addition, the PVD formed titanium/titanium nitride combination layer shows poor step coverage in a tungsten contact via with reduced size, thereby impacting the diffusion barrier performance thereof and the reliability of the tungsten contact.

Due to the critical dimension (CD) reduction of semiconductor devices, the size of the tungsten contact for electrically contacting the active regions formed on a semiconductor substrate or a gate electrode of a transistor is also reduced. Hence, a thinner and more reliable diffusion barrier for tungsten contact is needed to prevent undesired tungsten diffusion.

### SUMMARY

Semiconductor devices are provided. An exemplary semiconductor device comprises a substrate with at least one transistor formed thereon. A first dielectric layer covering the transistor provides an opening to expose an active region of the transistor. An tungsten-containing barrier is conformably formed in the opening, with a thickness of less than 50 Å. A tungsten layer is formed over the atomic layer deposited (ALD) tungsten-containing barrier to fill the opening.

A method for forming a semiconductor device is also provided, in which a substrate with at least one transistor covered by a first dielectric layer is provided. An opening is formed in the first dielectric layer to expose an active region of the transistor. A tungsten-containing barrier layer is conformably formed at a thickness less than 50 Å in the opening and a tungsten layer is formed over the tungsten-containing barrier layer to fill the opening.

A detailed description is given in the following embodiments with reference to the accompanying drawings.

### BRIEF DESCRIPTION OF THE DRAWINGS

The invention can be more fully understood by reading the subsequent detailed description and examples with reference made to the accompanying drawings, wherein:

FIGS. 1, 3-6 are cross sections of an embodiment of a method for forming a semiconductor device with a tungsten interconnect and a tungsten contact according to an embodiment of the invention; and

FIG. 2 shows an embodiment of a method of injecting source and purge gases in atomic layer deposition 165 of FIG. 1.

### DESCRIPTION

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers. By use of the term “low dielectric constant” or “low-k” herein, is meant a dielectric constant (k value) which is less than the dielectric constant of a conventional silicon oxide. Preferably, the dielectric constant of the low-k is less than about 3.9.

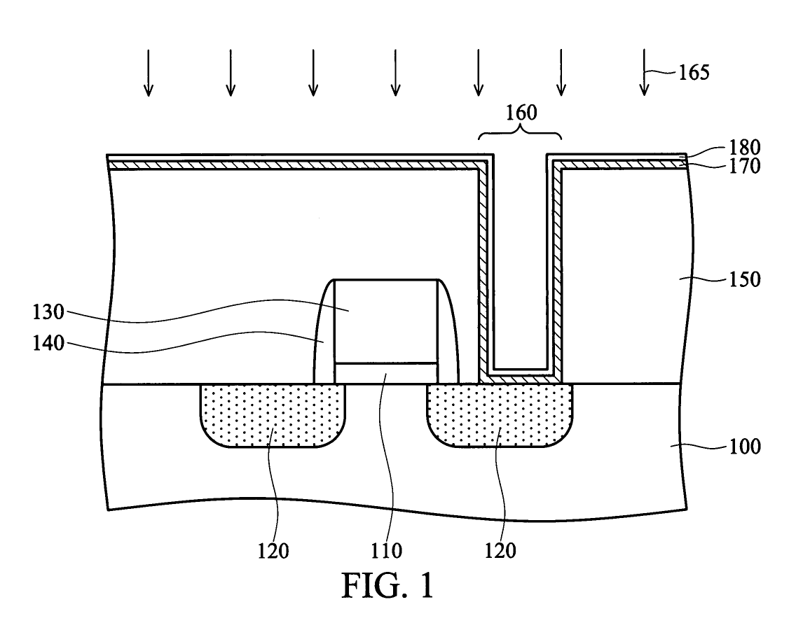

Semiconductor devices and fabrication methods thereof are provided. An exemplary embodiment of a method of fabricating semiconductor devices with tungsten contacts is shown in cross section in FIGS. 1-6. In FIG. 1, a substrate 100, such as a silicon substrate, is first provided with a transistor formed thereon. The transistor comprises a gate insulating layer 110 and a gate electrode 130 sequentially formed over a portion of the substrate 100, functioning as a gate stack, and the gate electrode 130 is insulated from the substrate 100 by the gate insulating layer 110. The transistor further comprises a pair of source/drain regions 120 oppositely disposed in the substrate 100 adjacent to the gate electrode 130. Preferably, the gate electrode 130 is polysilicon and can be doped with impurities of suitable conductive type, and the source/drain regions 120 are N type or P type doped. Further, the transistor comprises insulating spacers 140 formed on opposite sidewalls of the gate stack, respectively.

A first dielectric layer 150, preferably a phosphorous-containing dielectric layer of phosphosilicate glass (PSG) or borophosphosilicate glass (BPSG), is formed over the substrate 100 and the transistor with an opening 160 formed therein. The opening 160 can be formed at a position related to one of the active regions such as the source/drain region 120 or the gate electrode 130 of the transistor. Herein, as shown in FIG. 1, the opening 160 formed in a position corresponding to one of the source/drain regions 120, exposing the top surface thereof is given as an example but is not restricted thereto.

Next, a tungsten-containing barrier layer 170 at a thickness less than 50 Å and a tungsten seed layer 180 at a thickness of about 10-50 Å are sequentially and comfortably formed over the first dielectric layer 150 and in the opening 160. Thickness of the tungsten-containing barrier layer 170 is preferably between 30-50 Å and the tungsten-containing barrier layer 170 and the tungsten seed layer 180 are simultaneously formed by an atomic layer deposition (ALD) 165. The atomic layer deposition 165 can be performed by an atomic layer deposition cluster tool having multiple chambers (not shown). The tungsten-containing barrier layer 170 shows good step coverage in the opening 160 and provides better fluorine resistance, enhanced electromigration resistance compared to the conventional Ti/TiN barrier layer in a later formed conductive contact. The tungsten-containing barrier layer 170 may comprise boron tungsten (BxWy) with x between 1-10 and y between 1-10 or tungsten is nitride (WzN) with z between 1-10. The atomic layer deposition 165 for forming the tungsten-containing barrier layer 170 comprising the described materials and the tungsten seed layer 180 will be further discussed later.

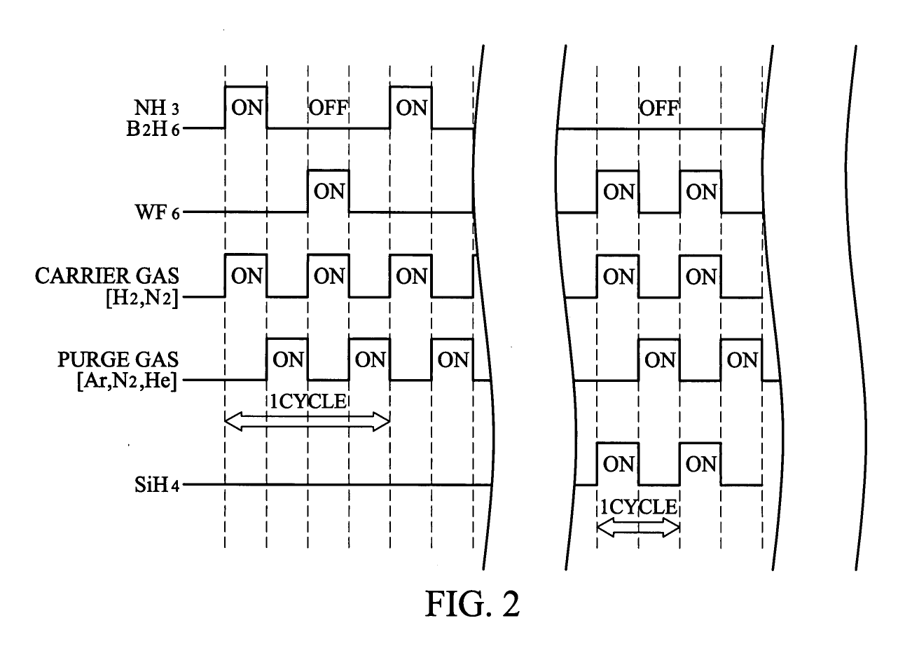

FIG. 2 shows an exemplary method for injecting gaseous reactants, purge gases and carrier gas during atomic layer deposition 165. Atomic layer deposition 165 is performed by an atomic layer deposition (ALD) cluster tool having multiple process chambers at a process pressure of about 5 torr and at a process temperature between 300° C.

When forming the tungsten-containing barrier layer 170 comprising tungsten nitride (WzN with z between 1-10), the reactants used include hexafluoride (WF₆) and ammonia (NH₃) with flow rates of about 50-100 sccm and 50-100 sccm, respectively. Moreover, when forming the tungsten-containing barrier layer 170 comprising boron tungsten (BxWy with x between 1-10 and y between 1-10), the reactants used may include hexafluoride (WF₆) and diborane (B₂H₆) with flow rates of about 50-100 sccm and 50-100 sccm, respectively.

Further, carrier gas such as hydrogen (H₂) or nitrogen (N₂) at a flow rate between 500-2000 sccm is also used in the atomic layer deposition 165 to carry the described reactants into the process chamber. Moreover, gases such as helium, nitrogen and argon with a total flow rate between 500-2000 sccm are used to purge reactants remaining in the process chamber. As shown in FIG. 2, purge operations are facilitated by injecting a purge gas in pulses between the injection pulses. Thus, a tungsten-containing layer 170 comprising tungsten nitride or boron tungsten is formed at a formation rate of about 1-3 Å/per cycle. The pulse-on time for the source gas is about 0.001-0.1 seconds. The tungsten-containing barrier layer 170 can thus be formed at least 5 described cycles.

As shown in FIG. 2, a cycle of NH₃/B₂H₆—WF₆ in cooperation with purge operations is performed by injecting a purge gas in pulses between the injection pulses, thus forming a tungsten-containing barrier layer 170 at a formation rate of about 1-3 Å/per cycle. The pulse-on time for the source gas is about 0.001-0.1 seconds. The tungsten-containing barrier layer 170 can thus be formed by at least 5 described cycles.

As shown FIG. 2, a SiH₄—WF₆ cycle in which purge operations are facilitated by injecting a purge gas in the form of a pulse between injection pulses is also illustrated. A tungsten seed layer 180 is thereby formed in situ during atomic layer deposition 165 at a formation rate of about 0.001-0.1 Å/per cycle. The tungsten seed layer 180 can thus be formed by at least 5 described cycles.

The reactants used in the formation of the tungsten seed layer can be hexafluoride (WF₆) and silane (SiH₄) with flow rates of about 50-100 sccm and 50-100 sccm, respectively. Further, carrier gas such hydrogen or nitrogen with a flow rate between 500-2000 sccm is also used to carry the gaseous reactants. In addition, purge gases such as helium, nitrogen and argon are used to purge the remaining reactant from the ALD tool chamber.

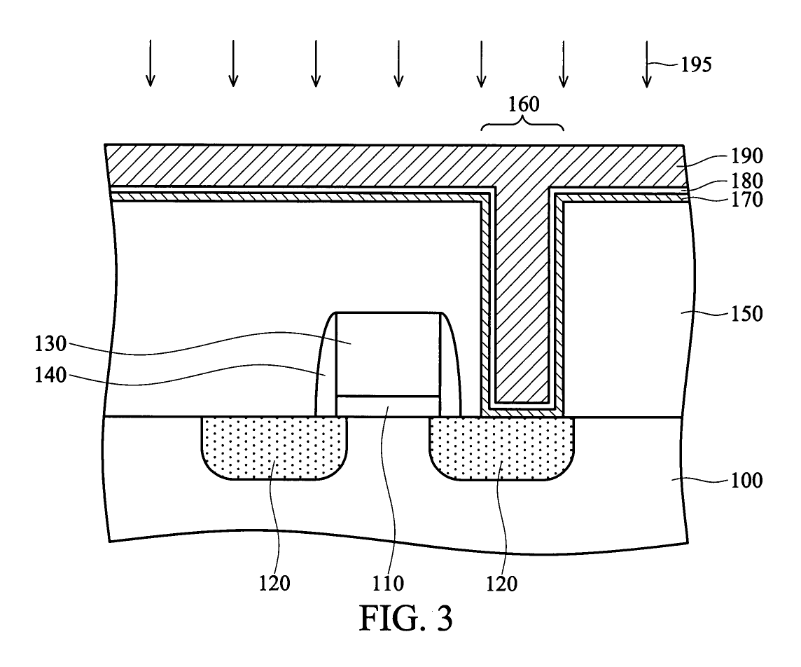

Next, in FIG. 3, a thick tungsten layer 190 is formed over the tungsten seed layer 170 and fills the opening by deposition 195. The deposition 195 can be a tungsten CVD using reactants such as hexafluoride (WF6) and silane (SiH₄). Due to the formation of the tungsten seed layer 180, the hexafluoride in the bulk tungsten formation is thus resisted by the underlying tungsten-containing barrier layer 170 and enhanced adhesion between the tungsten layer 190 and dielectric layer can be thus obtained.

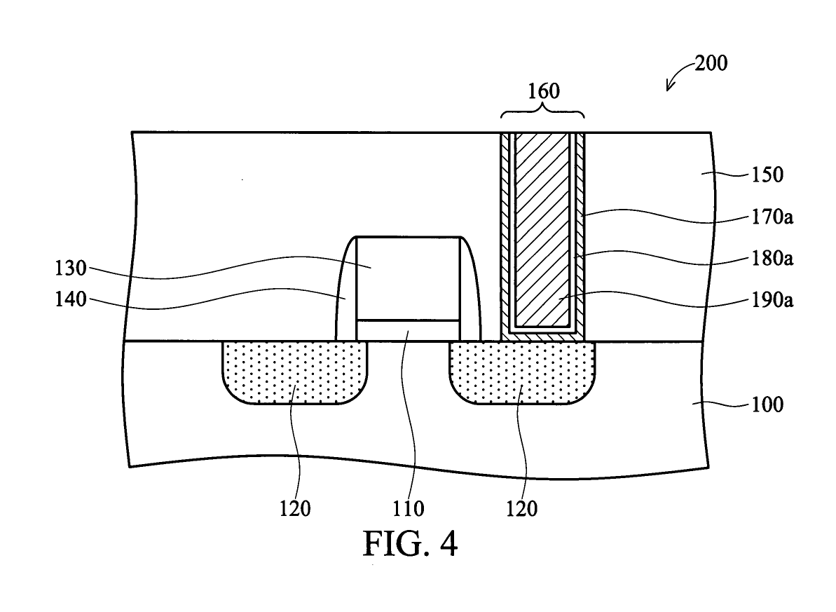

In FIG. 4, a planarization step, such as chemical mechanical polishing (CMP), is performed to remove the portion of the tungsten layer 190, the tungsten seed layer 180 and the tungsten-containing barrier layer 170 over the first dielectric layer 150, leaving a contact plug 200 as an interconnect between the underlying transistor and a substantially formed conductive line (not shown). Herein, the contact plug 200 comprises a conformal tungsten-containing barrier layer 170a, a tungsten layer 190a and a tungsten seed layer 180a therebetween, contacting the source/drain region 120 of the transistor. In the described CMP planarization step, the tungsten-containing barrier layer 170 is thin and can be simultaneously removed during the tungsten CMP, eliminating the need for additional CMP on the tungsten-containing barrier layer 170.

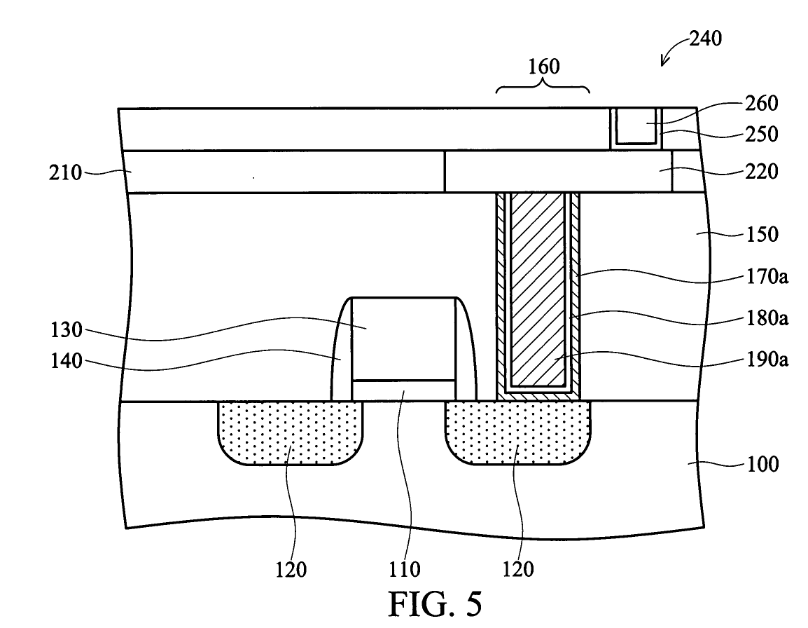

In FIG. 5, a second dielectric layer 210 with a conductive line 220, such as a tungsten line, formed therewith, is formed over the first dielectric layer 150 by conventional line fabrication process, wherein the conductive line 220 electrically connects the conductive plug 200. The second dielectric layer 210 can comprise a dielectric material such as phosphosilicate glass (PSG), borophosphosilicate glass (BPSG) or a low-k dielectric material with dielectric constant less than 3.9. A third dielectric layer 230 with a contact via 240 therein is formed over the second dielectric layer 210, the contact via 240 electrically connecting the conductive line 220. The third dielectric layer 230 can comprise a low-k dielectric material with dielectric constant less than 3.9. The contact via 240 comprises a metal barrier layer 250, a conductive layer 260, and a seed layer (not shown) formed by, for example, a conventional damascene process. The conductive layer 260 can be a tungsten layer and the metal barrier layer 250 can also be a tungsten-containing layer formed by the described atomic layer deposition 165. Thickness of the metal barrier layer 250 is thus reduced to provide a reliable contact via with reduced size. Thus, one of the source/drain regions 120 is electrically connected by the contact plug 200, the conductive line 220 and the contact via 240 in the upper level.

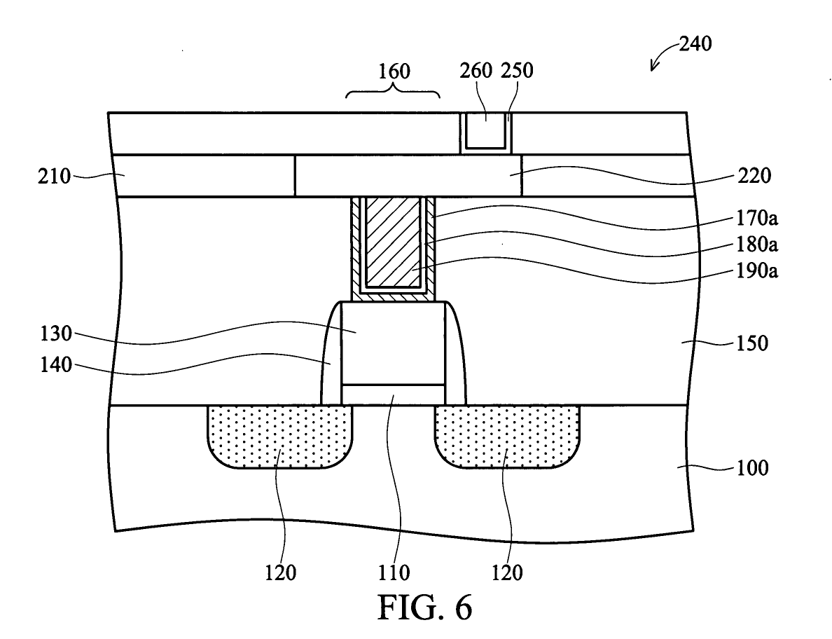

Moreover, the opening 160 can be formed in a position corresponding to the gate electrode 130 and the contact plug comprised of a conformal tungsten-containing barrier layer 170a, a tungsten layer 190a and a tungsten seed layer 180a can be sequentially formed therein by fabrication steps illustrated in FIGS. 3-4, as shown in FIG. 6.

In addition, in FIG. 6, the second dielectric layer 210 with a conductive line 220, such as a tungsten line, formed therewith, can be subsequently formed over the first dielectric layer 150 to electrically connect the conductive plug. Moreover, the third dielectric layer 230 with a contact via 240 comprised of the metal barrier layer 250 and the conductive layer 260, and a seed layer (not shown) therein can be subsequently formed over the second dielectric layer 210. The contact via 240 electrically connects the conductive line 220.

As shown in FIGS. 4 and 6, a semiconductor device with a tungsten contact is provided, comprising a substrate with at least one transistor thereon. A first dielectric layer covers the transistor and has an opening exposing an active region of the transistor. A tungsten-containing barrier layer thinner than a conventional Ti/TiN barrier layer is conformably formed in the opening by atomic layer deposition (ALD), and a tungsten layer is formed over the tungsten-containing barrier layer to fill the opening.

As shown in FIGS. 5 and 6, a tungsten interconnect is also provided on the semiconductor device, comprising an underlying conductive member (e.g. the conductive line 220) in a second dielectric layer. A third dielectric layer over the second dielectric layer has an opening therein, exposing a portion of the underlying conductive member. A tungsten-containing barrier layer is conformably formed in the opening by atomic layer deposition (ALD) with minimal thickness, and a tungsten layer over the tungsten-containing barrier layer fills the opening.

Semiconductor devices with tungsten contacts and have tungsten interconnects as disclosed both utilizing thin tungsten-containing barriers, formed with reduced thickness by ALD, providing optimal step coverage in openings. A reliable diffusion barrier to metals such tungsten is also achieved, making it a good choice for use in sub-100 nm semiconductor fabrication technology, and functioning as a diffusion barrier for a structure with smaller critical dimension (CD). The tungsten-containing barrier provides better step coverage, better fluorine resistance than conventional Ti/TiN barrier layer in a contact or interconnect and also exhibits maximum adhesion between a sequentially formed tungsten layer and a underlying dielectric layer thereof, thus providing a reliable tungsten contact and interconnect.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
at least one transistor on the substrate;
a first dielectric layer covering the transistor and having an opening exposing an active region of the transistor;
an tungsten-containing barrier conformably lining the opening, at a thickness less than 50 Å; and
a tungsten layer over the tungsten-containing barrier, filling the opening.

2. The semiconductor device of claim 1, wherein the tungsten-containing layer comprises boron tungsten (BxWy) with x between 1-10 and y between 1-10.

3. The semiconductor device of claim 1, wherein the tungsten-containing layer comprises tungsten nitride (WzN) with z between 1-10.

4. The semiconductor device of claimed in claim 1, wherein the first dielectric layer comprises phosphorous-containing dielectric material.

5. The semiconductor device of claim 4, wherein the phosphorous-containing dielectric is phosphosilicate glass (PSG) or borophosphosilicate glass (BPSG).

6. The semiconductor device of claim 1, further comprising a tungsten seed layer between the tungsten layer and the tungsten-containing barrier.

7. The semiconductor device of claim 1, wherein the tungsten-containing barrier is formed by atomic layer deposition (ALD).

8. A method for forming a semiconductor device, comprising:
providing a substrate with at least one transistor covered by a first dielectric layer;
forming a first opening in the first dielectric layer, exposing an active region of the transistor;
conformably forming a first tungsten-containing barrier at a thickness less than 50 Å in the first opening; and
forming a tungsten layer over the first tungsten-containing barrier layer, filling the first opening.

9. The method of claim 8, wherein the first dielectric layer comprises phosphorous-containing dielectric material.

10. The method of claim 9, wherein the phosphorous-containing dielectric material is phosphosilicate glass (PSG) or borophosphosilicate glass (BPSG).

11. The method of claim 8, wherein the first tungsten-containing barrier is formed by atomic layer deposition (ALD)

12. The method of claim 11, formation of the first tungsten-containing barrier comprising boron tungsten formed by alternatively reacting diborane (B₂H₆) and hexafluoride (WF₆) with the dielammonia (NH₃) with the first dielectric layer for at least 5 cycles.

13. The method of claim 8, wherein the first tungsten-containing barrier comprising tungsten nitride is formed by alternatively reacting ammonia (NH₃) and hexafluoride (WF₆) with the first dielectric layer for at least 5 cycles.

14. The method of claim 8, further comprising:
planarizing the tungsten layer, removing a portion of the tungsten layer over the first dielectric layer to expose the first dielectric layer and the tungsten layer in the first opening;
forming a second dielectric layer over the first dielectric layer and the tungsten layer;
forming a second opening in the second dielectric layer, exposing a portion of the tungsten layer;
conformably forming a second tungsten-containing barrier with a thickness less than 50 Å, in the second opening; and
forming a second tungsten layer over the second tungsten-containing barrier, filling the second opening.

15. The method of claim 14, wherein the second dielectric layer comprises phosphosilicate glass (PSG) or borophosphosilicate glass (BPSG).

16. The method of claim 14, wherein the second tungsten-containing barrier is formed by atomic layer deposition (ALD).

17. The method of claim 16, wherein formation of the second tungsten-containing barrier comprising:
alternatively reacting hexafluoride (WF₆) and diborane (B₂H₆) or ammonia (NH₃) with the first dielectric layer for at least 5 cycles.

18. The method of claim 8, further comprising a step of forming a tungsten seed layer on the first tungsten-containing barrier prior to the formation of the tungsten layer.

19. The method as claimed in claim 18, wherein the first tungsten-containing barrier layer and the tungsten seed layer are sequentially formed by an atomic layer deposition.

20. A method for forming a tungsten-containing layer, comprising:
providing a semiconductor device with an exposed dielectric portion;
alternatively reacting hexafluoride (WF₆) and diborane (B₂H₆) or ammonia (NH₃) with the exposed dielectric portion for at least 5 cycles to thereby form a tungsten-containing layer on the dielectric portion.

21. The method of claim 20, wherein the dielectric portion comprises phosphosilicate glass (PSG) or borophosphosilicate glass (BPSG) and the tungsten-containing layer is formed at a thickness less than 50 Å.
